(19) United States
(12) Patent Application Publication
(10) Pub. No.: US 2026/0295630 A1
(43) Pub. Date: Oct. 1, 2026

(54) METHOD AND SYSTEM FOR CATALYZED GAS-PHASE DEPOSITION OF POLYMERIC MATERIAL

(71) Applicant: ASM IP Holding B.V., Almere (NL)

(72) Inventors: Yen-Ting Lin, Hillsboro, OR (US); Kristina Paula Martinez, Phoenix, AZ (US); Krzysztof Kamil Kachel, Queen Creek, AZ (US); Adam Vianna, Phoenix, AZ (US); Eric Walter Eckert Vadelius, Hillsboro, OR (US)

(21) Appl. No.: 19/574,841

(22) Filed: Mar. 23, 2026

Related U.S. Application Data
(60) Provisional application No. 63/777,876, filed on Mar. 26, 2025.

(51) Int. Cl. B05D 1/00

(52) U.S. Cl. CPC B05D 1/60; B05D 2203/30; B05D 2320/00; B05D 2505/50

(57) ABSTRACT

Gas-phase methods of and reactor systems for depositing a layer of polymeric material on a surface of a substrate are disclosed. Exemplary methods include providing a reactant to a reaction chamber, providing a precursor to the reaction chamber, and providing a catalyst to the reaction chamber, wherein the catalyst catalyzes a polymerization reaction involving the precursor and the reactant to form the layer of polymeric material.

### CROSS-REFERENCE TO RELATED APPLICATIONS

This application is a nonprovisional of, and claims priority to and the benefit of, U.S. Provisional Patent Application No. 63/777,876, filed Mar. 26, 2025 and entitled “METHOD AND SYSTEM FOR CATALYZED GAS-PHASE DEPOSITION OF POLYMERIC MATERIAL,” which is hereby incorporated by reference herein.

### FIELD OF DISCLOSURE

The present disclosure relates generally to gas-phase deposition and systems. More particularly, the disclosure relates to gas-phase methods and systems for depositing polymeric material.

### BACKGROUND OF THE DISCLOSURE

Gas-phase deposition of polymeric material can be used for a variety of applications. For example, gas-phase deposition of polymeric material can be used in the formation of electronic devices, such as semiconductor devices.

In some semiconductor device fabrication processes, it may be desirable to form a material only on certain areas of a substrate. Typically, such results are achieved by depositing a continuous film of the material and subsequently patterning the continuous film using lithography and etch steps. Such lithography and etch processes may be time consuming and expensive. Further, such processes may not provide the precision or resolution desired for many applications.

Recently, techniques have been developed to allow for selective deposition of material on a first surface on a substrate relative to a second surface on the substrate without using photolithography. Selective deposition processes may take a number of forms, including, but not limited to, selective dielectric deposition on dielectric surfaces (DoD), selective dielectric deposition on metallic surfaces (DoM), selective metal deposition on dielectric surfaces (MoD), and selective metal deposition on metallic surfaces (MoM).

Gas-phase deposition of polymeric material can be used to facilitate selective deposition of material on a first surface relative to a second surface. While such techniques may work well for some applications, a uniformity of deposition and/or of polymerization may be less than desired. Additionally or alternatively, the deposited polymeric films may not exhibit desired (e.g., thermal) stability. Yet further, there is a general desire for gas-phase polymeric material processes to be performed at lower temperatures and/or at higher deposition rates for a given temperature. Accordingly, improved gas-phase deposition techniques to deposit polymeric material are desired.

Any discussion of problems and solutions described in this section has been included in this disclosure solely for the purposes of providing a context for the present disclosure. Such should not be taken as an admission that any or all of the discussion is prior art or was known at the time the invention was made.

### SUMMARY OF THE DISCLOSURE

This summary is provided to introduce a selection of concepts in a simplified form. Exemplary concepts are described in further detail in the detailed description of example embodiments of the disclosure below. This summary is not intended to necessarily identify key features or essential features of the claimed subject matter, nor is it intended to be used to limit the scope of the claimed subject matter.

In accordance with exemplary embodiments of the disclosure, methods of forming structures that include a layer of polymeric material are provided. Exemplary methods include providing a substrate in a reaction chamber of a reactor system, providing a reactant, providing a precursor to the reaction chamber, and providing a catalyst to the reaction chamber. In accordance with examples of these embodiments, the precursor includes at least one anhydride compound. In accordance with further examples, the reactant comprises an amine compound including at least two amine groups. The catalyst is configured to catalyze a polymerization reaction involving the precursor and the reactant to form the layer of polymeric material. In some cases, two or more of the steps of providing the precursor, providing the reactant, and providing the catalyst overlap. In some cases, two or more of the steps of providing the precursor, providing the reactant, and providing the catalyst do not overlap. In accordance with various examples, the method comprises a cyclical deposition process that includes one or more cycles. The one or more cycles can suitably include providing the precursor comprising pulsing the precursor to the reaction chamber for a precursor pulse period, providing the reactant comprising pulsing the reactant to the reaction chamber for a reactant pulse period, and/or providing the catalyst comprising pulsing the catalyst to the reaction chamber for a catalyst pulse period. In some cases, the catalyst can be flowed to the reaction chamber with the precursor and/or the reactant—e.g., to increase throughput. The reaction chamber can be purged between one or more pulse periods and/or between one or more cycles.

In accordance with additional embodiments, a structure is provided. The structure can include a substrate and a polymeric material, such as a polymeric film formed using a method and/or system as described herein.

In accordance with additional embodiments, a reactor system is provided. An exemplary reactor system includes a reaction chamber, a precursor source comprising a vessel and at least one anhydride compound therein, a reactant source comprising a vessel and at least one amine compound comprising at least two amine groups therein, a catalyst source comprising a vessel and at least one catalyst therein, and a controller. The controller can be configured to provide the precursor to the reaction chamber, provide the reactant to the reaction chamber, and provide a catalyst to the reaction chamber, to form the layer of polymeric material. The controller can be configured to perform one or more steps of method 100 in any combination.

For the purpose of summarizing the embodiments and the advantages achieved over the prior art, certain objects and advantages of the invention may have been described herein above. Of course, it is to be understood that not necessarily all such objects or advantages may be achieved in accordance with any particular embodiment. Thus, for example, those skilled in the art will recognize that the certain embodiments may be embodied or carried out in a manner that achieves or optimizes one advantage or group of advantages as taught or suggested herein without necessarily achieving other objects or advantages as may be taught or suggested herein.

All of these embodiments are intended to be within the scope of the disclosure. These and other embodiments will become readily apparent to those skilled in the art from the following detailed description of certain embodiments having reference to the attached figures, the disclosure not being limited to any particular embodiment(s) disclosed.

### BRIEF DESCRIPTION OF THE DRAWING FIGURES

A more complete understanding of the embodiments of the present disclosure may be derived by referring to the detailed description and claims when considered in connection with the following illustrative figures.

FIG. 1 illustrates a method in accordance with exemplary embodiments of the disclosure.

FIG. 2 illustrates a structure in accordance with examples of the disclosure.

FIG. 3 illustrates another structure in accordance with examples of the disclosure.

FIG. 4 illustrates a reactor system in accordance with examples of the disclosure.

FIG. 5 illustrates a reactor system having multiple reaction chambers, in accordance with examples of the disclosure.

It will be appreciated that elements in the figures are illustrated for simplicity and clarity and have not necessarily been drawn to scale. For example, the dimensions of some of the elements in the figures may be exaggerated relative to other elements to help improve understanding of illustrated embodiments of the present disclosure. The illustrations presented herein are not necessarily meant to be actual views of any particular material, structure, or system, but are merely representations that are used to describe embodiments of the disclosure.

### DETAILED DESCRIPTION OF EXEMPLARY EMBODIMENTS

Although certain embodiments and examples are disclosed below, it will be understood by those in the art that the invention extends beyond the specifically disclosed embodiments and/or uses of the invention and obvious modifications and equivalents thereof. Thus, it is intended that the scope of the invention disclosed should not be limited by the particular disclosed embodiments described below.

As set forth in more detail below, various embodiments of the disclosure provide methods of forming structures that include a layer of polymeric material. Methods described herein can be used to form structures that can be used to, for example, form electronic devices, such as semiconductor devices, microelectromechanical devices, photonic devices, and the like. For example, exemplary methods can be used to (e.g., selectively) form polymeric material on a surface of the substrate. The polymeric material may, in turn, be used to facilitate selective deposition of another material on another surface of the substrate. Thus, patterns of material can be formed without photolithography and/or etch processes.

As used herein, the term substrate can refer to any underlying material or materials that can be used to form, or upon which, a device, a circuit, or a film can be formed. A substrate can include a bulk material, such as silicon (e.g., single-crystal silicon), other Group IV materials, such as germanium, or other semiconductor materials, such as Group II-VI or Group III-V semiconductor materials, and can include one or more layers overlying or underlying the bulk material. Further, the substrate can include various features, such as recesses, protrusions, and the like formed within or on at least a portion of a layer of the substrate. By way of examples, a substrate can include semiconductor material. Exemplary substrates include a first surface of a first material and a second surface of a second material, wherein the first material and the second material are different.

As used herein, a structure can be or include a substrate as described herein. Structures can include a substrate and one or more layers overlying the substrate, such as one or more layers formed by a method according to the current disclosure.

As used herein, the term film and/or layer can refer to any continuous or non-continuous structure and material, such as material deposited by the methods disclosed herein. For example, a film and/or layer can include two-dimensional materials, three-dimensional materials, nanoparticles, partial or full molecular layers or partial or full atomic layers or clusters of atoms and/or molecules. A film or layer may partially or wholly consist of a plurality of dispersed atoms on a surface of a substrate and/or embedded in a substrate and/or embedded in a device manufactured on that substrate. A film or layer may comprise material or a layer with pinholes and/or isolated islands.

As used herein, the term metallic surface may refer to surfaces including a metallic component, including, but not limited to, metal surfaces (e.g., elemental metal or a metal alloy), metal oxide surfaces, metal silicide surfaces, metal nitride surfaces, metal carbide surfaces, mixtures thereof, and the like. The term metallic surface may also include a surface of a native oxide of a metallic material.

As used herein, the term silicon surface or silicon-containing surface may refer to a surface that includes silicon and that may include additional elements. Exemplary silicon-containing materials include, for example, silicon, silicon oxides, silicon nitrides, silicon oxynitrides, silicon carbides, silicon oxycarbides, silicon carbon nitride, and mixtures thereof.

The term cyclic deposition process or cyclical deposition process can refer to the sequential introduction of precursors (and/or reactants) into a reaction chamber to deposit a layer over a substrate and includes processing techniques, such as atomic layer deposition (ALD), molecular layer deposition, cyclical chemical vapor deposition (CCVD), and hybrid cyclical deposition processes that include an ALD component and a CCVD component. In some cases, a cyclical deposition process can include continually flowing one or more precursors, reactants, or inert gases, and pulsing other of the precursors or reactants. The term molecular layer deposition (MLD) may refer to a vapor deposition process in which one or more deposition cycles are conducted in a process chamber. Typically, during each cycle an organic precursor is adsorbed (e.g., chemisorbed) on a surface (e.g., a substrate surface or a previously deposited underlying surface, such as material from a previous MLD cycle), typically forming a single molecular layer that does not readily react with additional organic precursor (i.e., a self-limiting reaction). Thereafter, if desired, another precursor (e.g., another organic precursor or reactant) may subsequently be introduced into the process chamber for use in forming the desired organic material on the surface. Purging steps may also be utilized during each cycle to remove excess organic precursor and/or reactants from the process chamber and/or remove reaction byproducts from the process chamber after formation of the desired organic material.

As used herein, the term purge can refer to a procedure in which an inert or substantially inert gas is provided to a reaction chamber in between two pulses of gases that might otherwise react with each other. For example, a purge, e.g., using an inert gas, such as a noble gas, may be provided between a precursor pulse and a reactant pulse to reduce gas phase interactions between the precursor and the reactant that might otherwise occur. It shall be understood that a purge can be effected either in time or in space, or both. For example, in the case of temporal purges, a purge step can be used, e.g., in the temporal sequence of providing a precursor to a reaction chamber, providing a purge gas to the reaction chamber, and providing a reactant or another precursor to the reaction chamber, wherein the substrate on which a layer is deposited does not move. In the case of spatial purges, a purge step can take the following form: moving a substrate from a first location to which a precursor is (e.g., continually) supplied, through a purge gas curtain, to a second location to which a reactant or other precursor is (e.g., continually) supplied.

In this disclosure, continuously or continuous can refer to without breaking a vacuum, without interruption as a timeline, without any material intervening step, without changing treatment conditions, immediately thereafter, as a next step, or without an intervening discrete physical or chemical structure between two structures other than the two structures in some embodiments and depending on the context.

Further, in this disclosure, any two numbers of a variable can constitute a workable range of the variable, and any ranges indicated may include or exclude the endpoints. Additionally, any values of variables indicated (regardless of whether they are indicated with the term about or not) may refer to precise values or approximate values and include equivalents, and may refer to average, median, representative, majority, or the like. For example, the term about can refer to +/−20, 10, 5, 2, or 1 percent of a value. The terms comprising, including, constituted by and having refer independently to typically or broadly comprising, comprising, consisting essentially of, or consisting of in some embodiments. In this disclosure, any defined meanings do not necessarily exclude ordinary and customary meanings, in some embodiments.

Although a number of example materials are given throughout the embodiments of the current disclosure, it should be noted that the chemical formulas given for each of the example materials should not be construed as limiting and that the non-limiting example materials given should not be limited by a given example stoichiometry.

Various examples of the disclosure relate to selectively forming material on one surface relative to another surface. Selectivity of forming or deposing material can refer to a relatively higher amount of material formed or deposited on a surface relative to another surface. For example, selectivity of deposition on surface A relative to surface B can be given as a percentage calculated by [(deposition on surface A)-(deposition on surface B)]/(deposition on surface A). Deposition can be measured in any of a variety of ways. For example, deposition may be given as the measured thickness of the deposited material or may be given as the measured amount (e.g., weight) of material deposited.

As set forth in more detail below, in embodiments described herein, selective deposition of a layer of polymeric material can be conducted on a first surface (A) relative to a second surface (B). Subsequently, another material may be selectively deposited on the second surface (A) relative to the passivation film (B). In some embodiments, selectivity is greater than about 10%, or greater than about 50%, or greater than about 75%, or greater than about 85%, or greater than about 90%, or greater than about 93%, or greater than about 95%, or greater than about 98%, or greater than about 99%, or even greater than about 99.5%. In some embodiments, selective deposition only occurs on one surface and does not occur on the other surface. It will be appreciated that a partially selective process can result in a fully selective structure by, for example, a post-deposition treatment.

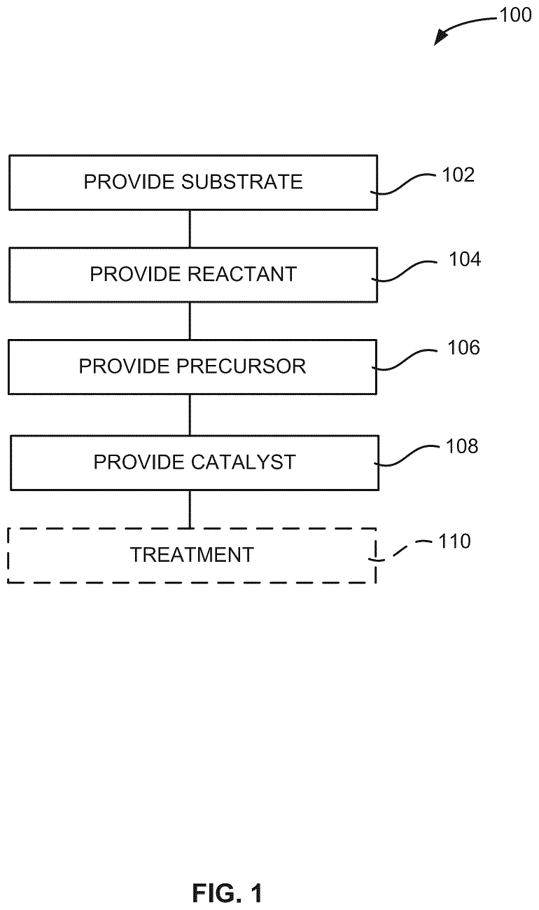

Turning now to the figures, FIG. 1 illustrates a method 100 of forming a structure comprising a layer of polymeric material in accordance with embodiments of the disclosure. Method 100 includes the steps of providing a substrate within a reaction chamber of a reactor (102), providing a reactant (104), providing a precursor (106), and providing a catalyst (108). Method 100 can also optionally include a treatment step (110). Although separately illustrated, two or more steps of method 100 may overlap in time, as described in more detail below.

During step 102, a substrate is provided within a reaction chamber. The reaction chamber can be a standalone reaction chamber or part of a cluster tool, such as a cluster tool described in more detail below. The reaction chamber can include a substrate heater to heat a substrate to a temperature noted herein. Additionally or alternatively, the reaction chamber can include rapid thermal processing apparatus, such as lamps, to heat the substrate.

The reaction chamber may be configured for performing all, or a portion, of the steps of method 100. In some embodiments of the disclosure, a first reaction chamber may be configured to perform one or more steps of method 100 and further reaction chamber(s) may be employed for other steps of method 100. However, in additional embodiments of the disclosure, the first reaction chamber may be configured to perform all of the steps of method 100.

Reactors and associated reaction chamber(s) capable of performing one or more steps of method 100 include atomic/molecular layer deposition (ALD/MLD) reaction chambers, plasma enhanced atomic layer deposition (PEALD) reaction chambers, as well as chemical vapor deposition (CVD) reaction chambers equipped with appropriate equipment and means for providing precursors. According to some embodiments, a showerhead reaction chamber may be used. According to some embodiments, a plasma reaction chamber, such as a PEALD reaction chamber, may be used. In such embodiments, the plasma may be direct, remote, or in near vicinity of the substrate. In some embodiments, the reactor is a spatial ALD or MLD reactor, in which the substrate moves or rotates during processing. In some cases, the reactor is a thermal reactor.

In some embodiments, a batch reactor may be used. In some embodiments, a vertical batch reactor is utilized in which the boat rotates during processing. For example, a vertical batch reactor may comprise a reaction chamber and an elevator constructed and arranged to move a boat configured for supporting a batch of between 10 to 200 substrates in or out of the reaction chamber.

In other embodiments, the batch reactor comprises a mini-batch reactor configured to accommodate 10 or fewer wafers, 8 or fewer wafers, 6 or fewer wafers, 4 or fewer wafers, or 2 wafers. In some embodiments in which a batch reactor is used, wafer-to-wafer non-uniformity is less than 3% (1 sigma), less than 2%, less than 1% or even less than 0.5%.

Method 100 can optionally be carried out in a reactor and associated reaction chambers that form a cluster tool. In a cluster tool, each reaction chamber may be dedicated to one type of process, such that, for example, a temperature of the reaction chamber in each module can be kept constant, which can improve the throughput, compared to a reaction chamber in which the substrate is heated up to the process temperature before each run. Additionally, in a cluster tool, it is possible to reduce the time to pump the reaction space to the desired process pressure levels between substrates. In some embodiments of the disclosure, a stand-alone reactor can be equipped with a load-lock. In that case, it may not be necessary to cool down the reaction space between each run.

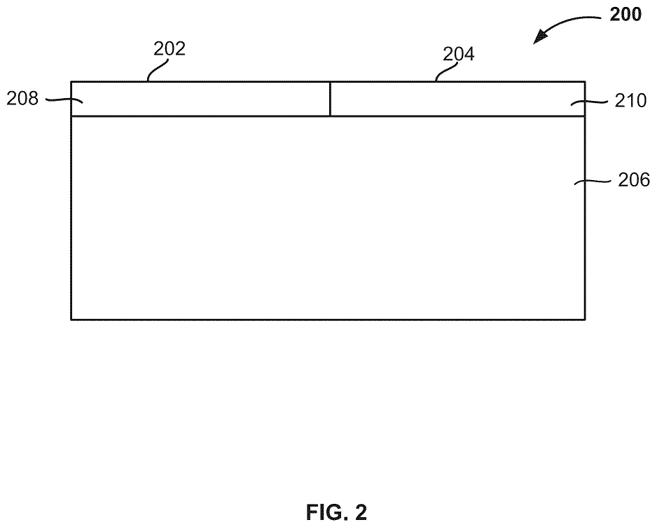

FIG. 2 illustrates a substrate 200 that can be supplied during step 102. Substate 200 provided during step 102 can include a first surface 202 and a second surface 204 and optionally a bulk layer or material 206. First surface 202 can include a first material 208 and second surface 204 can include a second material 210 different than first material 208.

In various examples, first surface 202 is or includes a metal carbide, metal oxide, metal nitride, metal boride, elemental metal, metallic surface, amorphous carbon, an alloy of two or more metals, or a combination thereof. In some examples, the first surface comprises a metal comprising aluminum (Al), copper (Cu), tungsten (W), cobalt (Co), nickel (Ni), niobium (Nb), iron (Fe), molybdenum (Mo), indium (In), gallium (Ga), manganese (Mn), zinc (Zn), ruthenium (Ru), titanium (Ti), tantalum (Ta), chromium (Cr) or vanadium (V), or a combination thereof. In some cases, the first surface does not comprise silicon. In some cases, the first surface can include a plurality of metal-containing materials. For example, the first surface can include a liner or barrier layer material and a fill material, such as a metal or metal alloy.

In various examples, the second surface is a dielectric surface comprising SiCOₓ, SiOₓ, silicon, SiO₂, zirconium oxide (ZrO₂), hafnium oxide (HfO₂), aluminum oxide (Al₂O₃), titanium nitride (TiN) and titanium oxide (TiO₂), or aluminum nitride (AlN), or a combination thereof. In some examples, the second surface comprises RuOₓ, NiOₓ, CoOₓ, NbOₓ, MoOₓ, WOₓ, NbBₓ, NbCₓ, WNCₓ, TaN, or TiN, or a combination thereof. In some cases, the second surface comprises silicon. In some cases, the second surface comprises a passivation blocking layer formed thereon. When the second surface includes a blocking layer, the first surface may include a dielectric or insulating or other material layer.

In certain examples, the passivation blocking layer comprises a self-assembled monolayer (SAM) or an alkylsilane having at least one alkoxy group bonded to a silicon atom. Example SAMs to serve as passivation blocking layers (“inhibitors”) are disclosed in U.S. patent application Ser. No. 17/388,773, filed Jul. 29, 2021, the entire disclosure of which is incorporated herein by reference for all purposes to the extent the disclosure does not conflict with the present disclosure. Example alkylsilane passivation blocking layers (“inhibitors”) are disclosed in U.S. Provisional Patent Application No. 63/583,732,filed Sep. 19, 2023, the entire disclosure of which is incorporated herein by reference for all purposes. Examples of selective deposition of alkylsilanes that can serve as the passivation blocking layers include an alkylsilane, such as bis(tert-pentoxy)methylsilanol, tris(tert-pentoxy)silanol, tris(tert-butoxy)silanol (TBS), tris(isopropoxy)silanol (TIS), or tris(tert-pentoxy)silanol (TPS), bis(tert-pentoxy)methylsilanol, bis(tert-butoxy)methylsilanol or bis(tert-pentoxy)ethylsilanol.

In another example, the inhibitor may be represented by formula:

SiₐRₓ(OH)_{y}(OR′)_{z}

where: a is 1, 2 or 3, x is 1, 2 or 3, y is 0, 1 or 2, and z is 1, 2 or 3, with the proviso that x+y+z=a+2, and each R and R′ is independently selected from linear and branched C1 to C8 alkyls.

In an example, R′ of Formula 1 is selected from isopropyl, sec-butyl, tert-butyl, 1,1-dimethylpropyl, 2,2-dimethylpropyl, 1-methylbutyl, 3-methylbutyl, 3-pentyl, 1,2-dimethylpropyl and 2-methylbutyl. In an example, R is methyl or ethyl.

Once the substrate has been loaded into a suitable reaction chamber, the substrate may be heated to a suitable temperature—e.g., for a degas or for subsequent step 104. By way of examples, the substrate can be heated to a temperature of about 150° C. to about 250° C. or about 250° C. to about 400° C. A pressure within the reaction chamber during step 102 can be between about 1 and about 5 Torr or between about 5 and about 10 Torr.

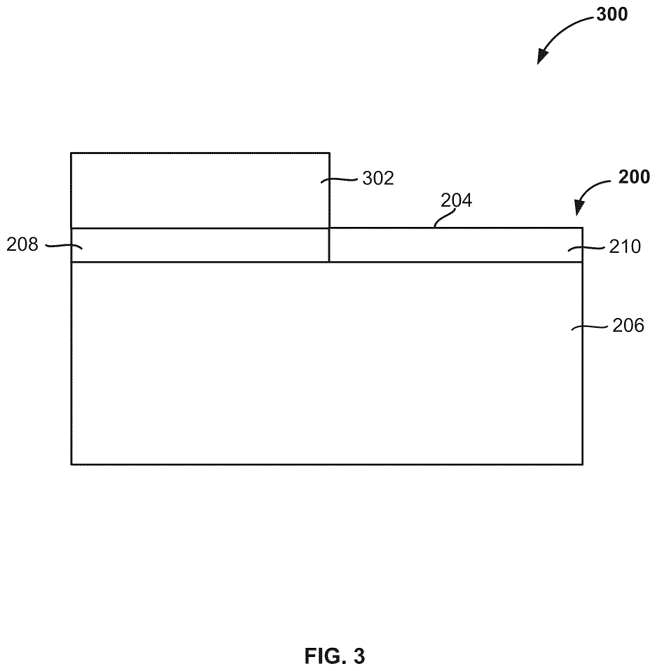

During steps 104-108, a layer of polymeric material is deposited on a surface of a substrate. In some cases, the polymeric material can be selectively deposited on the first surface, relative to the second surface. FIG. 3 illustrates a structure 300 including a layer of polymeric material 302 selectively deposited on first surface 202.

In accordance with examples of the disclosure, the layer of polymeric material is or includes organic material. In accordance with particular examples, the layer of polymeric material comprises one or more of a polyimide, polyamide, dimer, trimer, polyurethane, polythiourea, polyester, polyimine or another polymer layer capable of (e.g., selectively) forming on first surface 202.

Various precursors and reactants can be used to deposit the first material. Exemplary polymeric material precursors and/or reactants include polyimide precursors, SAM precursors, and the like.

In some embodiments, polymeric material precursors/reactants for use in the selective deposition of an organic polymer may be aliphatic compounds comprising 1-6 carbon atoms, 2-5 carbon atoms, 2-4 carbon atoms, 5 or fewer carbon atoms, 4 or fewer carbon atoms, 3 or fewer carbon atoms, or 2 carbon atoms. In some embodiments, the bonds between carbon atoms in the reactant or precursor may be single bonds, double bonds, triple bonds, or some combination thereof.

With reference again to FIG. 1, during step 104, a reactant is provided to the reaction chamber. In accordance with examples of the disclosure, the reactant comprises an amine compound. In various examples, the reactant comprises a diamine, a triamine, a tetraamine, a cyclic compound comprising at least two primary amines, or a combination thereof. Thus, in accordance with examples of the disclosure, step 104 includes providing a reactant, comprising an amine compound comprising at least two amine groups, to the reaction chamber.

In some embodiments, the reactant comprises two amino groups. In some embodiments, the amino groups of the reactant may occupy one or both terminal positions on an aliphatic carbon chain. However, in some embodiments, the amino groups of the reactant may not occupy either terminal position on an aliphatic carbon chain. In some embodiments, the reactant may comprise a diamine. In some embodiments, the reactant may comprise one or more of 1,2-diaminoethane, 1,3-diaminopropane, 1,4-diaminobutane, 1,5-diaminopentane, 1,2-diaminopropane, 2,3-butanediamine, 2,2-dimethyl-1,3-propanediamine.

The reactant may comprise at least two carbon atoms, such as 1,2-diaminoethane. In some embodiments, the reactant comprises three carbon atoms. In some embodiments, the reactant comprises four carbon atoms. For example, the reactant may be selected from 1,2-diaminobutane, 1,3-diaminobutane, 1,4-diaminobutane and 2,4-diaminobutane. Thus, in some embodiments, at least one of the amino groups is attached to a carbon atom that is bonded to two other carbon atoms. In other words, at least one of the amino groups may be located at the end of a carbon chain. In some embodiments, a diamine according to the current comprises five carbon atoms. In some embodiments, a diamine according to the current comprises six carbon atoms.

In some embodiments, the carbon chain of the reactant is branched. In such cases, there can be at least one carbon atom which is bonded to three or four other carbon atoms. In some embodiments, there is one such branching position in the reactant. In some embodiments, there are two such branching positions in the reactant. In some embodiments, there are three or more branching points. In some embodiments, the side chain from the longer carbon chain is a methyl group. In some embodiments, the side chain from the longer carbon chain is an ethyl group. In some embodiments, the side chain from the longer carbon chain is a propyl group. In some embodiments, the side chain from the longer carbon chain is an isopropyl group. In some embodiments, the side chain from the longer carbon chain is a butyl group. In some embodiments, the side chain from the longer carbon chain is a tert-butyl group. In some embodiments, the side chain of a reactant is a straight alkyl chain. In some embodiments, the side chain of a reactant is a branched alkyl chain. In some embodiments, the side chain of a reactant is a cyclic alkyl chain.

In some embodiments, the reactant is a C2 to C11 compound. The number of carbon atoms in the reactant typically influences the volatility of the compound, such that a higher-weight compound may not be as volatile as a smaller compound. However, it was found out that intermediate-sized first organic polymer precursors containing, for example, four, five or six carbon atoms, may have suitable properties for being used as a reactant in a deposition process according to the current disclosure. For example, 1,3-diaminopentane is liquid at room temperature, has a boiling point of 164° C. under atmospheric pressure, a vapor pressure of about 2.22 Torr at 25° C. and reaches a vapor pressure of 1 Torr at temperatures below 20° C. Thus, when 1,3-diaminopentane is used as a reactant for polymeric material deposition according to the current disclosure, the precursor vessel does not need to be heated. This may be advantageous for the on-tool lifetime of the precursor, as it may be less prone to degradation during continued use. Further, a liquid precursor has an advantage that precursor vessel loading is less expensive than for solid precursors. In some embodiments, the reactant comprises 1,3-diaminopentane.

In some embodiments of the disclosure, the amine groups of the reactant are attached to non-adjacent carbon atoms. This may have advantages for the availability for the amine groups to reactions with the precursor. In some embodiments, there is one carbon atom between the amino group-binding carbon atoms. In some embodiments, there is at least one carbon atom between the amino group-binding carbon atoms. In some embodiments, there are two carbon atoms between the amino group-binding carbon atoms. In some embodiments, there are at least two carbon atoms between the amino group-binding carbon atoms. In some embodiments, there are three carbon atoms between the amino group-binding carbon atoms. In some embodiments, there are at least three carbon atoms between the amino group-binding carbon atoms. In some embodiments, there are four carbon atoms between the amino group-binding carbon atoms. In some embodiments, there are at least four carbon atoms between the amino group-binding carbon atoms.

In some embodiments, the reactant comprises 1,5-diamino-2-methylpentane. Although the vapor pressure of 1,5-diamino-2-methylpentane is lower than that of 1,3-diaminopentane, it is also liquid at ambient temperature, and reaching vapor pressure of 1 Torr requires a moderate temperature of about 40° C.

In some embodiments, a carbon atom bonded with an amine nitrogen in reactant is bonded to at least two carbon atoms. Thus, in some embodiments in which the reactant comprises five or more carbons, at least one of the amino groups may be located away from the end of a carbon chain. The structure of the reactant affects its properties in a vapor deposition process. Branching of a first organic polymer precursor, including the number of branches, and the relative position of the amino groups to the branches, may cause the deposited organic polymer to have different properties. Without limiting the current disclosure to any specific theory, for example, steric factors, may lead to certain reactions being preferred. This may offer the possibility to design a deposition process for a given purpose, taking into account, for example, the thermal budget, organic polymer growth speed requirements, degree of selectivity, by using different reactants.

In some embodiments, the reactant is a cyclic diamine. In some embodiments, the reactant comprises a cyclopentanedialkylamine, cyclohexanedialkylamine, cyclopentadienedialkylamine, benzenedialkylamine, cyclopentanetrialkylamine, cyclohexanetrialkylamine, cyclopentadienetrialkylamine and benzenetrialkylamine.

In some embodiments, the reactant is an aromatic diamine. In some embodiments, the aromatic diamine is a diaminobenzene, such as 1,2-diaminobenzene, 1,3-diaminobenzene or 1,4-diaminobenzene. In some embodiments, the aromatic diamine comprises an alkylamino group in at least one position. For example, the alkylamino group may be a C1 to C3 alkylamino group, such as —CH₂NH₂, —(CH₂)₂NH₂, —(CH₂)₃NH₂, —CH(CH₃)NH₂ or —CH₂CH(CH₃)NH₂.

In some embodiments, the reactant is selected from a group consisting of 1,3-diaminopentane, 1,4-diaminopentane, 2,4-diaminopentane, 2,4-diamino-2,4-dimethylpentane, 1,5-diamino-2-methylpentane, 1,3-diaminobutane, 1,3-diamino-3-methylbutane, 2,5-diamino-2,5-dimethylhexane, 1,4-diamino-4-methylpentane, 1,3-diaminobutane, 1,5-diaminohexane, 1,3-diaminohexane, 2,5-diaminohexane, 1,3-diamino-5-methylhexane, 4,4,4-trifluoro-1,3-diamino-3-methylbutane, 2,4-diamino-2-methylpentane, 4-(1-methylethyl)-1,5-diaminohexane, 3-aminobutanamide, 1,3-diamino-2-ethylhexane, 2,7-diamino-2,7-dimethyloctane, 1,3-diaminobenzene and 1,4-diaminobenzene. In some embodiments, the reactant comprises a halogen.

In some embodiments, triamines may be used as a reactant in the deposition of polymeric material. Providing such molecules may advantageously affect the availability of polymerization sites for the precursor, described below. The availability of three amine groups in a single molecule may lead to a denser polymer network, which again may reduce the metal migration through the organic polymer. Such properties may be advantageous in embodiments utilizing the organic polymer according to the current disclosure as a passivation layer. Examples of suitable triamines include 1,2,3-triaminopropane, triamino butane (with amines in carbons 1, 2 and 3 or in carbons 1, 2 and 4), triamino pentane (especially with amines in carbons 1 and 5, plus in any one of the carbons 2, 3 or 4). Similarly, triamino hexanes may contain amine groups in carbons 1 and 6, as well as in any one of the positions 2, 3, 4 or 5; triamino heptanes may contain amine groups in carbons 1 and 7, as well as in any one of the positions 2, 3, 4, 5 or 6; and triamino octanes may contain amine groups in carbons 1 and 8, as well as in any one of the positions 2, 3, 4, 5, 6 or 7. Further, branched carbon chains, notably 2-aminomethyl-1,3-diaminopropane, 2-aminomethyl-1,4-diaminobutane (or alternatives having the two amino groups elsewhere in the butane chain), 2-aminomethyl-1,5-diaminopentane (or alternatives having the two amino groups elsewhere in the pentane chain), 3-aminomethyl-1,5-diaminopentane (or alternatives having the two amino groups elsewhere in the pentane chain), 2-aminomethyl-1,6-diaminohexane (or alternatives having the two amino groups elsewhere in the hexane chain), 3-aminomethyl-1,6-diaminohexane (or alternatives having the two amino groups elsewhere in the hexane chain), 3-aminoethyl-1,6-diaminohexane (or alternatives having the two amino groups elsewhere in the hexane chain). Also, an aromatic triamine, such as 1,3,5-triaminobenzene, may be an alternative for certain embodiments.

In some embodiments, the reactant for use in the selective cyclical deposition processes described herein may have the general formula:

R¹(NH₂)₂

wherein R¹ may be an aliphatic carbon chain comprising 1-5 carbon atoms, 2-5 carbon atoms, 2-4 carbon atoms, 5 or fewer carbon atoms, 4 or fewer carbon atoms, 3 or fewer carbon atoms, or 2 carbon atoms.

By way of particular examples, the reactant can be selected from the group consisting of 1,2-diaminoethane (I), 1,3-diaminopropane (I), 1,4-diaminobutane(I), 1,5-diaminopentane (I), 1,2-diaminopropane (I), 2,3-butanediamine, 2,2-dimethyl-1,3-propanediamine (I), 1,6-diaminohexane, 1,4 diaminocyclohexane, or any other monomer with two reactive groups, tris(2-aminoethyl)amine, or a cyclic compound comprising at least two primary amine groups, such as 1,4-diaminocyclohexane (noted above) or p-phenylenediamine.

During step 106, a precursor is provided to the reaction chamber. In some embodiments, the precursor is an organic reactant capable of reacting with adsorbed species of the reactant under the deposition conditions. In some cases, the terms reactant and precursor can be used interchangeably.

In some embodiments, the precursor is an anhydride compound, such as furan-2,5-dione (maleic acid anhydride). The anhydride can be a dianhydride, e.g., pyromellitic dianhydride. In some embodiments, the precursor can be any other monomer with two reactive groups that will react with the reactant to form the polymeric material. In some cases, the precursor comprises one or more of an anhydride or a dianhydride compound or a dianhydride comprising a thioanhydride group.

In some embodiments, the precursor and/or reactant does not contain metal atoms. In some embodiments, the precursor and/or reactant does not contain semimetal atoms. In some embodiments, one of the precursor and/or reactant comprises metal or semimetal atoms. In some embodiments, the precursor and/or reactant contains carbon and hydrogen and one or more of the following elements: N, O, S, P or a halide, such as Cl or F.

In some embodiments, a precursor comprises an organic compound selected from the group of 1,4-diisocyanatobutane, or 1,4-diisocyanatobenzene. In some embodiments, the precursor comprises an organic precursor selected from the group of: terephthaloyl dichloride, alkyldioyl dichlorides, such as hexanedioyl dichloride, octanedioyl dichloride, nonanedioyl dichloride, decanedioyl dichloride, or terephthaloyl dichloride. In some embodiments, the precursor comprises an organic precursor selected from the group of 1,4-diisothiocyanatobenzene, or terephthalaldehyde. In some embodiments, the precursor being vaporized can also be a diamine, such as, for example, 1,4-diaminobenzene, decane-1,10-diamine, 4-nitrobenzene-1,3-diamine, 4,4′-oxydianiline, or ethylene diamine. In some embodiments, the precursor can be a terephthalic acid bis(2-hydroxyethyl) ester. In some embodiments, the precursor can be a carboxylic acid, for example, alkyl-, alkenyl-, alkadienyl-dicarboxylic or tricarboxylic acid, such as ethanedioic acid, propanedioic acid, butanedioic acid, pentanedioic acid or propane-1,2,3-tricarboxylic acid. In some embodiments, the precursor can be an aromatic carboxylic or dicarboxylic acid, such as benzoic acid, benzene-1,2-dicarboxylic acid, benzene-1,4-dicarboxylic acid or benzene-1,3-dicarboxylic acid. In some embodiments, the precursor may comprise one or more OH-groups bonded to a hydrocarbon. In some embodiments, the precursor can be selected from the group of diols, triols, aminophenols, such as 4-aminophenol, benzene-1,4-diol or benzene-1,3,5-triol. In some embodiments, the precursor can be 8-quinolinol. In some embodiments, the precursor can comprise alkenylchlorosilanes, like alkenyltrichlorosilanes, such as 7-octenyltrichlorosilane.

A temperature within a reaction chamber during step 106 can be between about 100° C. and about 200° C. or between about 200° C. and about 400° C. A pressure within the reaction chamber can be between about 0 Torr and about 5 Torr or between about 5 Torr and about 20 Torr.

During step 108, a catalyst is provided to the reaction chamber. The catalyst is configured to catalyze a polymerization reaction involving the precursor and the reactant to form the layer of polymeric material.

In accordance with examples of the disclosure, the catalyst comprises a nitrogen-containing compound. In accordance with examples of the disclosure, the nitrogen-containing compound comprises a base. In accordance with further examples, the nitrogen-containing compound can be represented by the chemical formula

NR₃

where each R is independently selected from a C1-C6 alkyl group or is H. In accordance with further examples, a lone pair of electrons is present on the nitrogen in the above formula. In some cases, each R can be the same. For example, the catalyst can be or include triethylamine.

In accordance with additional examples, the nitrogen-containing compound comprises a cyclic structure. In some cases, the nitrogen-containing compound comprises a heterocyclic structure. In some cases, the nitrogen-containing compound comprises a cyclic structure, where N is included in part of the ring structure. In some cases, the nitrogen-containing compound comprises an alkyl (e.g., branched or linear C1-C4) or aromatic or tertiary amine (e.g., tertiary substituted amine) substituted pyridine. By way of particular examples, the nitrogen-containing compound can include one or more of triethylamine, quinoline, isoquinoline, 2-methyl-pyridine, 2,6,-dimethylpyridine, 1,4-diazabicyclo[2.2.2]octane, 1,8-diazabicycloe[5.4.0]undec-7-ene, N-N-dimethylaniline, tri-trimethylsilyl amine, pyrrolidine, piperidine, pyridine, aminopyridine, other picolines, piperazine, other lutidines, or methylamine.

Steps 104-108 can be performed using a cyclical deposition process. A cyclical deposition process can include one or more cycles, wherein one or more cycles of the cyclical deposition process includes providing the precursor comprises pulsing the precursor to the reaction chamber for a precursor pulse period, providing the reactant comprises pulsing the reactant to the reaction chamber for a reactant pulse period, and/or providing the catalyst comprises pulsing the catalyst to the reaction chamber for a catalyst pulse period. For example, one or more cycles can include pulsing the precursor to the reaction chamber for the precursor pulse period, pulsing the reactant to the reaction chamber for the reactant pulse period, and pulsing the catalyst to the reaction chamber for a catalyst pulse period. In some cases, one or more cycles can include pulsing the precursor to the reaction chamber for the precursor pulse period, pulsing the catalyst to the reaction chamber for a first catalyst pulse period, pulsing the reactant to the reaction chamber for the reactant pulse period, and pulsing the catalyst to the reaction chamber for a second catalyst pulse period.

A duration of a reactant pulse period can be between about 50 msec and about 100 seconds or between about 100 msec and about 5 seconds. A duration of a precursor pulse period can be between about 50 msec and about 100 seconds or between about 50 msec and about 100 seconds. A duration of a catalyst pulse period can be between about 50 msec and about 100 seconds or between about 100 msec and about 5 seconds.

The cyclical deposition process can further include a purge between one or more steps and/or cycles. For example, a purge step can be performed between the pulsing the precursor and the pulsing the reactant or any other steps.

Various steps 104-108 can overlap. For example, the steps of providing the precursor and providing the catalyst overlap in time. Additionally or alternatively, the steps of providing the reactant and providing the catalyst overlap in time. In some cases, the catalyst can be flowed with the precursor and/or the reactant to the reaction chamber.

A thickness of the layer of polymeric material (e.g., layer 302) can be between about 0.1 nm and about 2.5 nm or between about 2.5 nm and about 7.5 nm. A selectivity of the first material deposited on the second surface relative to the first surface can be as described above.

As illustrated in FIG. 1, method 100 can include an optional treatment step 110. In some cases, step 110 includes one or more of a direct plasma treatment, a remote plasma treatment, a UV treatment, an e-beam treatment, or use of other energetic beams. In some cases, step 110 includes providing one or more gases to a reaction chamber. The one or more gases can be used to form excited species using one or more of the excitation techniques noted herein. Such gases can include one or more of Ar, N₂, He, Ne, O₂, H₂ and any mixtures thereof.

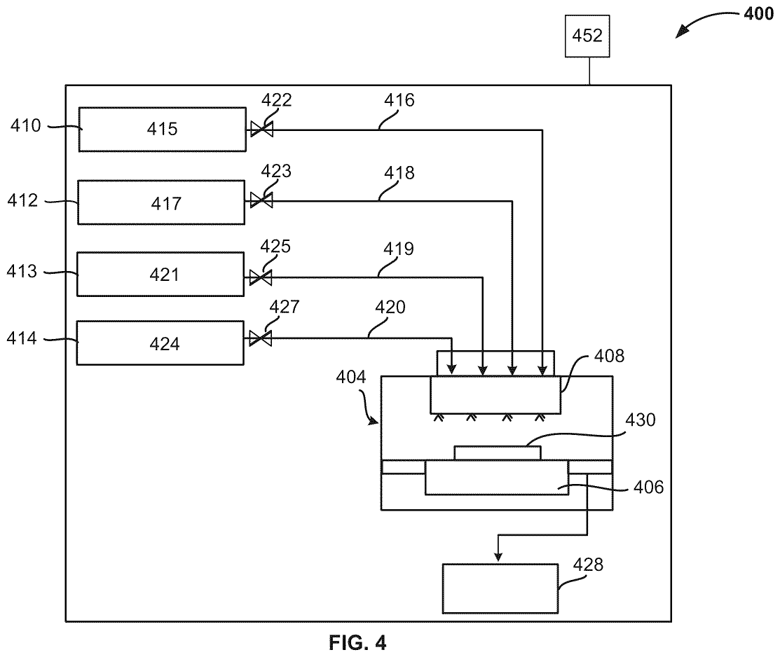

Referring now to FIG. 4, in various examples, a reactor system 400 includes a reaction chamber 404, a susceptor 406 to hold a substrate 430 during processing, a gas distribution system 408 (e.g., a showerhead) to distribute one or more precursors and/or reactants to a surface of substrate 430, one or more precursor or reactant sources 410, 412, and/or 413, and/or a carrier and/or purge gas source 414, fluidly coupled to reaction chamber 404 via respective lines 416, 418, 419 and 420, and respective valves or controllers 422, 423, 425 and 427. Substrate 430 can include a substrate or structure as described herein. A purge/carrier gas 424 from gas source 414 can be flowed to and through reaction chamber 404 to act as a carrier gas, and/or purge or remove any excess reactant or other undesired materials from reaction chamber 404. Sources 410, 412 and 413 can include vessels and a precursor or reactant as described herein. For example, source 410 can include a vessel and a reactant 415; source 412 can include a vessel and a precursor 417; source 413 can include a vessel and catalyst 421. Reactor system 400 can include additional sources. System 400 can also include a vacuum source 428 fluidly coupled to the reaction chamber 404. Vacuum source 428 can be configured to evacuate reactants, a purge gas, or other materials out of reaction chamber 404.

Reactor system 400 also includes a controller 452. Controller 452 can be configured to perform various functions and/or steps as described herein. Controller 452 can include one or more microprocessors, memory elements, and/or switching elements to perform the various functions. Although illustrated as a single unit, controller 452 can alternatively comprise multiple devices. Controller 452 can be used to control gas flow (e.g., by monitoring flow rates and controlling valves 422, 423, 425 and/or 427), motors, heaters, cooling devices and/or vacuum source 428 to execute various processes (e.g., one or more (e.g., all) steps of method 100). Further, when a system includes two or more reaction chambers, as described in more detail below, the two or more reaction chambers can be coupled to the same/shared controller. By way of example, controller 452 can be configured to provide the reactant to the reaction chamber, provide the precursor to the reaction chamber, and provide a catalyst to the reaction chamber, to form the layer of polymeric material.

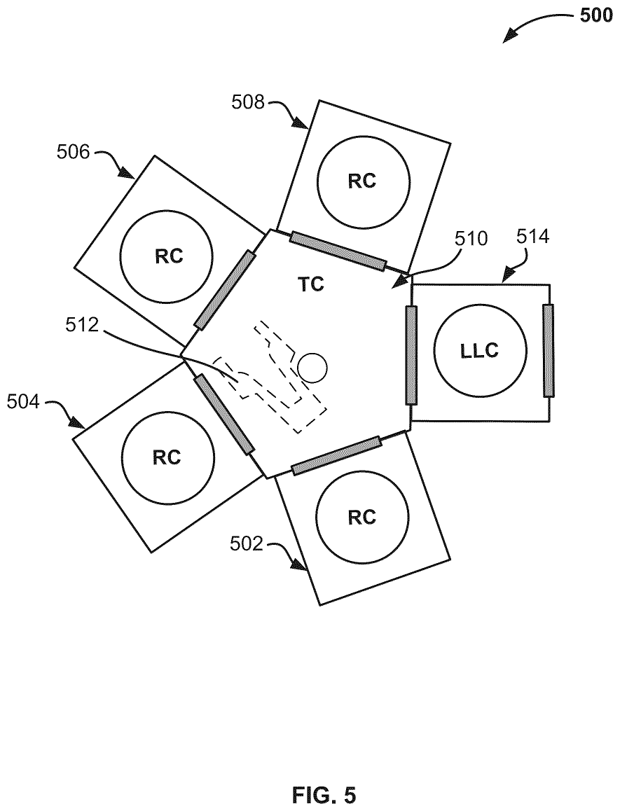

FIG. 5 illustrates a reactor system 500 that includes a plurality of reaction chambers 502-508, each of which can be an example of reaction chamber 404 in FIG. 4. Reaction chambers 502-508 can be disposed around and/or coupled to a transfer chamber 510 that includes a transfer tool 512 for transferring substrates between reaction chambers 502-508 and a load lock chamber 514 and between reaction chambers 502-508 (e.g., through transfer chamber 510). For example, a substrate 430 can be disposed in different chambers for different steps of a method described herein. For example, one of reaction chambers 502-508 can be used to form a structure comprising a layer of polymeric material and another of the reaction chambers can be used to treat the layer of polymeric material. Other configurations are also possible, such that one or more steps of method 100 are performed within a single reaction chamber.

The example embodiments of the disclosure described above do not limit the scope of the invention, since these embodiments are merely examples of the embodiments of the invention, which is defined by the appended claims and their legal equivalents. Any equivalent embodiments are intended to be within the scope of this invention. Indeed, various modifications of the disclosure, in addition to those shown and described herein, such as alternative useful combinations of the elements described, may become apparent to those skilled in the art from the description. Such modifications and embodiments are also intended to fall within the scope of the appended claims.

1. A method of forming a structure comprising a layer of polymeric material, the method comprising:
providing a substrate in a reaction chamber of a reactor of a reactor system;
providing a reactant, comprising an amine compound comprising at least two amine groups, to the reaction chamber;
providing a precursor, comprising at least one anhydride compound, to the reaction chamber; and
providing a catalyst to the reaction chamber,
wherein the catalyst catalyzes a polymerization reaction involving the precursor and the reactant to form the layer of polymeric material.

2. The method of claim 1, wherein the polymeric material comprises a polyimide layer.

3. The method of claim 1, wherein the method comprises a cyclical deposition process comprising one or more cycles, and wherein, for the one or more cycles:
the providing the precursor comprises pulsing the precursor to the reaction chamber for a precursor pulse period;
the providing the reactant comprises pulsing the reactant to the reaction chamber for a reactant pulse period; and/or
the providing the catalyst comprises pulsing the catalyst to the reaction chamber for a catalyst pulse period.

4. The method of claim 3, wherein the one or more cycles comprise:
pulsing the precursor to the reaction chamber for the precursor pulse period;
pulsing the reactant to the reaction chamber for the reactant pulse period; and
pulsing the catalyst to the reaction chamber for the catalyst pulse period.

5. The method of claim 4, comprising a purge step between the pulsing the precursor and the pulsing the reactant.

6. The method of claim 3, wherein the one or more cycles comprise:
pulsing the precursor to the reaction chamber for the precursor pulse period;
pulsing the catalyst to the reaction chamber for a first catalyst pulse period;
pulsing the reactant to the reaction chamber for the reactant pulse period; and
pulsing the catalyst to the reaction chamber for a second catalyst pulse period.

7. The method of claim 1, wherein the steps of providing the precursor and providing the catalyst overlap in time.

8. The method of claim 1, wherein the steps of providing the reactant and providing the catalyst overlap in time.

9. The method of claim 1, wherein the precursor comprises one or more of an anhydride or a dianhydride compound.

10. The method of claim 9, wherein the dianhydride compound comprises pyromellitic dianhydride or a dianhydride comprising a thioanhydride group.

11. The method of claim 1, wherein the reactant comprises one or more of a diamine, triamine, tetraamine, or cyclic compound comprising two primary amine groups.

12. The method of claim 1, wherein the catalyst comprises a nitrogen-containing compound.

13. The method of claim 12, wherein the nitrogen-containing compound comprises a base.

14. The method of claim 12, wherein the nitrogen-containing compound comprises a cyclic structure.

15. The method of claim 12, wherein the nitrogen-containing compound comprises a heterocyclic structure.

16. The method of claim 12, wherein the nitrogen-containing compound comprises a alkyl or aromatic or tertiary amine substituted pyridine.

17. The method of claim 12, wherein the nitrogen-containing compound comprises one or more of triethylamine, quinoline, isoquinoline, 2-methyl-pyridine, 2,6,-dimethylpyridine, 1,4-diazabicyclo[2.2.2]octane, 1,8-diazabicycloe[5.4.0]undec-7-ene, N-N-dimethylaniline, or tri-trimethylsilyl amine.

18. The method of claim 1, wherein the substrate comprises a first surface and a second surface, and wherein the layer of polymeric material is selectively formed on the first surface relative to the second surface.

19. The method of claim 18, wherein the first surface comprises a metal carbide, a metal oxide, a metal nitride, a metal boride, an elemental metal, a metallic surface, amorphous carbon, or a combination thereof.

20. A reactor system comprising:
a reaction chamber;
a precursor source comprising a vessel and at least one anhydride compound therein;
a reactant source comprising a vessel and at least one amine compound comprising at least two amine groups therein;
a catalyst source comprising a vessel and at least one catalyst therein; and
a controller configured to:
provide a precursor to the reaction chamber;
provide a reactant to the reaction chamber; and
provide a catalyst to the reaction chamber, to form a layer of polymeric material.
